(19) United States
(12) Patent Application Publication
(10) Pub. No.: US 2025/0309087 A1
(43) Pub. Date: Oct. 2, 2025

(54) POWER CHIP PACKAGE STRUCTURE AND MANUFACTURING METHOD THEREOF

(71) Applicant: TONG HSING ELECTRONIC INDUSTRIES, LTD., Taipei City (TW)

(72) Inventors: Yu-Te Hsieh, Taipei City (TW); Zzu-Chi Chiu, Taipei City (TW); Wei-Chung Chao, Taipei City (TW); Yan-Wei Chen, Taipei City (TW)

(73) Assignee: TONG HSING ELECTRONIC INDUSTRIES, LTD., Taipei City (TW)

(21) Appl. No.: 18/675,154

(22) Filed: May 28, 2024

(30) Foreign Application Priority Data
Mar. 28, 2024 (TW) 113111578

(51) Int. Cl. H01L 23/498; H01L 23/00; H01L 23/373

(52) U.S. Cl. CPC H01L 23/49838; H01L 23/3735; H01L 24/32; H01L 24/33; H01L 24/83; H01L 2224/32225; H01L 2224/33181; H01L 2224/8384

(57) ABSTRACT

The present invention provides a power chip package structure and a manufacturing method thereof. The power chip package structure includes a carrier, a plurality of supporting portions, a conductive paste, and a power chip. The carrier includes a ceramic board and an inner metal layer that is formed on the ceramic board. The inner metal layer has a connection pad and a plurality of carrying regions spaced apart from each other and arranged outside of the connection pad. The supporting portions are respectively formed on the carrying regions, and the conductive paste is disposed on the connection pad. The power chip includes a chip body disposed on the supporting portions and a bonding pad that is formed on the chip body. The bonding pad is connected to the conductive paste, such that the power chip is electrically coupled to the carrier.

### BACKGROUND OF THE INVENTION

### 1. Field of the Invention

The present invention relates to a package structure, and in particular to a power chip package structure and a manufacturing method thereof.

### 2. Description of the Prior Art

The power chip in the package structure is prone to tilt, which may cause problems of poor reliability. Therefore, the inventor believed that the above-mentioned defects could be improved, so he devoted himself to research and applied scientific principles, and finally proposed an invention that is reasonably designed and effectively improves the above-mentioned defects.

### SUMMARY OF THE INVENTION

Embodiments of the present invention provide a power chip package structure and a manufacturing method thereof, which can effectively improve the defects that may occur in the existing power chip package structure.

An embodiment of the present invention discloses a method for manufacturing a power chip package structure, which includes: a pre-step: providing a first carrier including a first ceramic board and a first inner metal layer formed on an inner plate surface of the first ceramic board; wherein the first inner metal layer includes at least one first connection pad and a plurality of first carrying regions spaced apart from each other and located outside of the at least one first connection pad; a first build-up step: forming a plurality of supporting parts on the plurality of first carrying regions, which are jointly defined as a first supporting portion; a configuring step: disposing at least one first conductive paste on the at least one first connection pad, and a top edge of the at least one first conductive paste is not lower than a top edge of the first supporting portion; a chip placement step: using a jig to place a power chip on the first supporting portion and the at least one first conductive paste, so that at least one first bonding pad of the power chip is connected to the at least one first conductive paste; and a curing step: heating and sintering the at least one first conductive paste through the jig so that the power chip is fixed to the at least one first conductive paste.

An embodiment of the present invention discloses a power chip package structure, which includes: a first carrier including a first ceramic board and a first inner metal layer formed on an inner surface of the first ceramic board; wherein the first inner metal layer includes at least one first connection pad, and a plurality of first carrying regions spaced apart from each other and located outside of the at least one first connection pad; a first supporting portion including a plurality of supporting parts respectively formed on the plurality of first carrying regions of the first inner metal layer; at least one first conductive paste disposed on the at least one first connection pad; and a power chip including: a chip body having a first surface and an opposing second surface, and the first surface of the chip body is disposed on the first supporting portion; and at least one first bonding pad formed on the first surface of the chip body; wherein the at least one first bonding pad is connected to the at least one first conductive paste, so that the power chip is electrically coupled to the first carrier.

To sum up, in the power chip package structure and the manufacturing method thereof disclosed in the embodiments of the present invention, the first supporting portion is disposed between the first carrier and the power chip, so that during the production process of the power chip package structure, the power chip can be maintained in a preset position by the first supporting portion, thereby preventing the power chip from being tilted relative to the first carrier, so as to achieve better reliability performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a three-dimensional schematic diagram of a power chip package structure according to Embodiment I of the present invention.

FIG. 2 is a schematic cross-sectional view taken along line II-II of FIG. 1.

FIG. 3 is a schematic top view of the power chip package structure according to Embodiment I of the present invention (the second module and the molding compound are omitted).

FIG. 4 is a schematic flowchart of a method for manufacturing a power chip package structure according to Embodiment I of the present invention.

FIG. 5 is a schematic cross-sectional view showing the pre-step, the first build-up step, and the second build-up step of FIG. 4.

FIG. 6 is a schematic top view of FIG. 5.

FIG. 7 is a schematic top view showing the second build-up step of FIG. 4.

FIG. 8 is a schematic cross-sectional view showing the configuring step of FIG. 4.

FIG. 9 is a schematic cross-sectional view showing the chip placement step and the curing step in FIG. 4.

FIG. 10 is a schematic cross-sectional view of the power chip package structure of Embodiment II of the present invention.

### DETAILED DESCRIPTION

The following is a specific example to illustrate the implementation of the “power chip package structure and manufacturing method thereof” disclosed in the present invention. Those skilled in the art can understand the advantages and effects of the present invention from the content disclosed in this specification. The present invention can be implemented or applied through other different specific embodiments, and various details in this specification can also be modified and changed based on different viewpoints and applications without departing from the concept of the present invention. In addition, the drawings of the present invention are only simple schematic illustrations and are not depictions based on actual dimensions, as is stated in advance. The following embodiments will further describe the relevant technical content of the present invention in detail, but the disclosed content is not intended to limit the scope of the present invention.

It should be understood that although terms such as “first”, “second” and “third” may be used herein to describe various elements or signals, these elements or signals should not be limited by these terms. These terms are primarily used to distinguish one component from another component or one signal from another signal. In addition, the term “or” used in this article shall include any one or combination of more of the associated listed items depending on the actual situation.

### Embodiment I

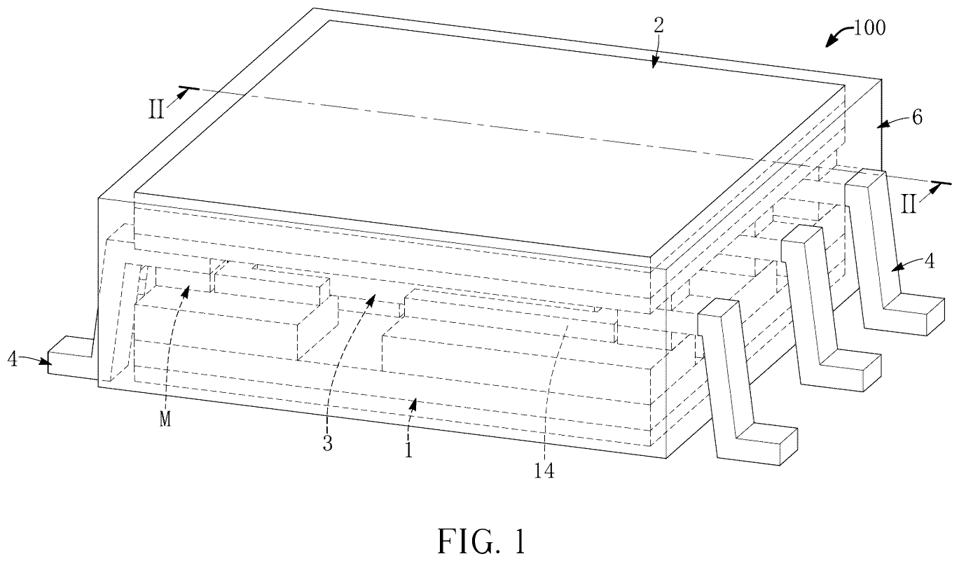

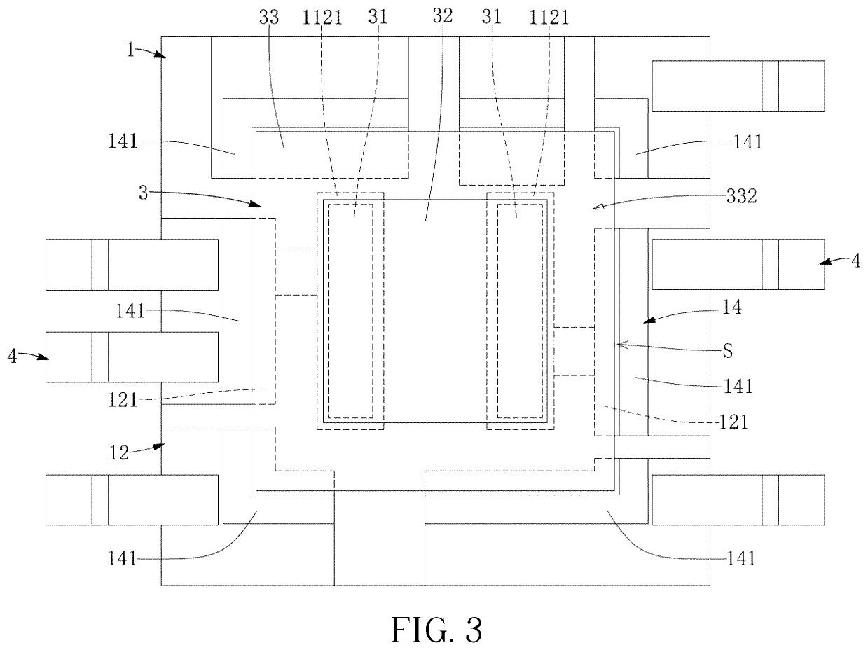

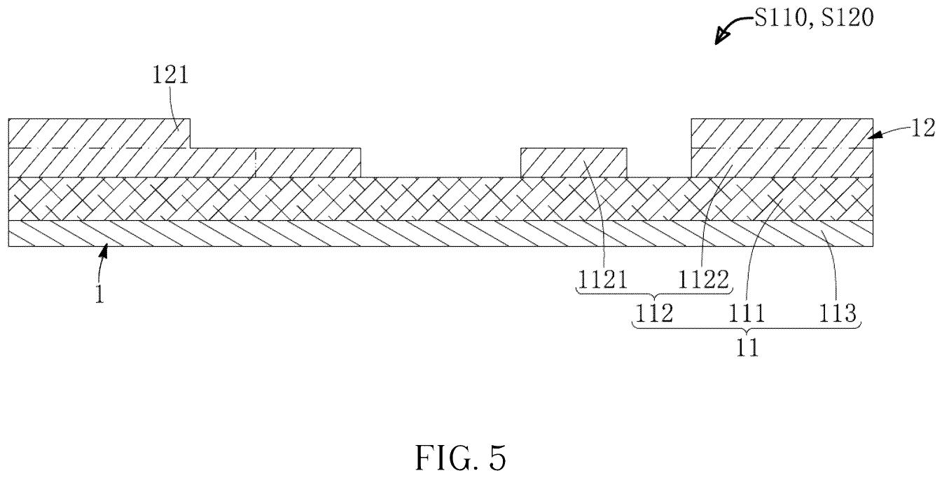

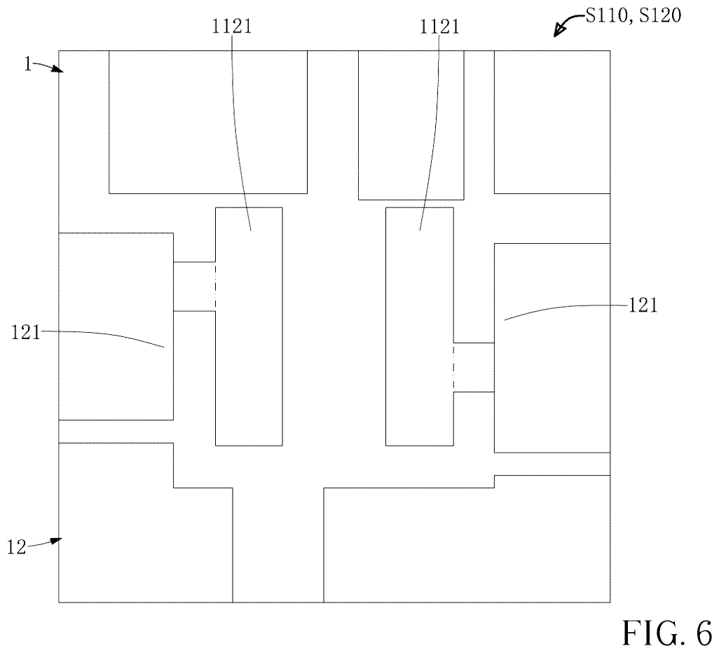

Please refer to FIG. 1 to FIG. 9, which illustrate Embodiment I of the present invention. This embodiment discloses a power chip package structure 100 and its manufacturing method S100. To facilitate the description of this embodiment, the structure of each component of the power chip package structure 100 and its connection relationship will be introduced first, and then the main implementation steps of the power chip package structure manufacturing method S100.

As shown in FIG. 1 to FIG. 3, the power chip package structure 100 adopts a wire-less architecture in this embodiment, and the power chip package structure 100 includes a first module 1, a second module 2 spaced apart from the first module 1, a power chip 3 clamped and fixed between the first module 1 and the second module 2, and multiple pins 4 spaced apart from each other and disposed around the power chip 3.

The power chip 3 comprises a chip body 33, two first bonding pads 31 formed on one side of the chip body 33, and a second bonding pad 32 formed on the other side of the chip body 33. In this embodiment, the chip body 33 has a first surface 331 and a second surface 332 opposite to the first surface 331. The two first bonding pads 31 are formed on the first surface 331 and are spaced apart from each other. The two first bonding pads 31 may be a source pad and a gate pad, respectively. The second bonding pad 32 is formed on the second surface 332 and may be a drain pad, but not limited thereto.

It is noteworthy that the type of the power chip 3 can be adjusted and changed according to actual needs. For example, the power chip 3 may be an insulated gate bipolar transistor (IGBT), a power MOSFET, a bipolar junction transistor (BJT), a silicon carbide (SiC) power device, a gallium nitride (GaN) power device, a high electron mobility transistor (HEMT), or a fast recovery diode (FRD). Further, the number of the power chip 3 can also be adjusted according to actual needs.

In this embodiment, the first module 1 includes a first carrier 11, a first supporting portion 12 and two first conductive pastes 13 formed on the first carrier 11, and a positioning portion 14 on the first supporting portion 12, but not limited thereto. For example, in some embodiments not shown in the instant disclosure, the positioning portion 14 may be omitted or replaced with other structures according to actual needs.

The first carrier 11 includes a first ceramic board 111, a first inner metal layer 112 formed on the inner plate surface of the first ceramic board 111, and a first outer metal layer 113 formed on the outer plate surface of the first ceramic board 111. In this embodiment, the first carrier 11 is a direct plated copper (DPC) ceramic substrate, and the first inner metal layer 112 and the first outer metal layer 113 are plated on the inner plate surface and the outer plate surface of the first ceramic board 111, respectively, but not limited thereto. For example, in some embodiments, the first inner metal layer 112 and the first outer metal layer 113 may be formed by direct bonded copper (DBC) technology or formed by using active metal brazing (AMB) technology on the inner plate surface and the outer plate surface of the first carrier 11, respectively.

Furthermore, the first inner metal layer 112 comprises two spaced-apart first connection pads 1121 and a plurality of first carrying regions 1122 arranged outside of the two first connection pads 1121. Each of the first connection pads 1121 may be connected to one of the first carrying regions 1122, and the first inner metal layer 112 is formed with a plurality of gaps surrounding the two first connection pads 1121. From another perspective, except for the two first connection pads 1121, the layout of other parts of the first inner metal layer 112 can be adjusted and changed according to actual needs.

The first supporting portion 12 includes a plurality of supporting parts 121 respectively formed on the plurality of first carrying regions 1122, and each of the first connection pads 1121 can be electrically coupled to the corresponding supporting member 121 through the connected first carrying region 1122. Furthermore, the positioning portion 14 is formed on the plurality of supporting parts 121, so that the positioning portion 14 and the plurality of supporting parts 121 jointly define a positioning slot S. In this embodiment, the positioning portion 14 includes a plurality of protrusions 141, which are respectively provided on the plurality of supporting parts 121 to form the boundary of the positioning slot S.

More specifically, the material of the first inner metal layer 112 and the material of the first supporting portion 12 are both conductive materials (e.g., copper). The supporting part 121 and the first supporting portion 12 may be an integrated single-piece structure formed by a semiconductor process, but not limited thereto. For example, in some embodiments not shown in the instant disclosure, the material of the first inner metal layer 112 and the material of the first supporting portion 12 may be different conductive materials.

Furthermore, the positioning portion 14 may be made of insulating material. The insulating material may be photosensitive resin (PR), molding compound, plastic polymer, low modulus polymer, or liquid crystal polymer (LCP), but not limited thereto. For example, in some embodiments not shown in the instant disclosure, the protrusions 141 made of conductive material can be formed on any of the supporting parts 121 that are not connected to the pins 4.

As shown in FIG. 1 to FIG. 3, the two first conductive pastes 13 are respectively disposed on the two first connection pads 1121 of the first inner metal layer 112, and in this embodiment, each of the first conductive pastes 13 may be a sintering silver paste, but not limited thereto.

The power chip 3 is disposed in the positioning slot S and the first surface 331is disposed on the first supporting portion 12. The two first bonding pads 31 are respectively connected to the two first conductive pastes 13 so that the power chip 3 is electrically coupled to the first carrier 11. More specifically, the bottom of the power chip 3 is located within the positioning slot S, and the top of the power chip 3 protrudes from the positioning slot S. The plurality of supporting parts 121 of the first supporting portion 12 abut the first surface 331 of the chip body 33, and each of the first conductive pastes 13 is not connected to the first carrying region 1122.

It should be noted that the number of the first connection pads 1121 and the number of the first conductive pastes 13 are two for each in this embodiment, which correspond to the two first bonding pads 31 of the power chip 3. However, the invention is not limited thereto. It is to be understood that the number of the first connection pads 1121, the number of the first bonding pads 31, and the number of the first conductive pastes 13 can also be adjusted to at least one for each according to actual needs.

As disclosed above, the power chip package structure 100 in this embodiment employs the first supporting portion 12 that is interposed between the first carrier 11 and the power chip 3 so that during the production process of the power chip package structure 100, the power chip 3 can be continuously supported by the plurality of first supporting portions 12 and maintained in a preset position, thereby preventing the power chip 3 from being tilted relative to the first carrier 11 so as to achieve better reliability performance.

The second module 2 includes a second carrier 21, a second supporting portion 22 and a second conductive paste 23 formed on the second carrier 21. The second carrier 21 includes a second ceramic board 211, a second inner metal layer 212 formed on the inner plate surface of the second ceramic board 211, and a second outer metal layer 213 formed on the outer plate surface of the second ceramic board 211.

In this embodiment, the second carrier 21 is a direct plated copper (DPC) ceramic substrate, and the second inner metal layer 212 and the second outer metal layer 213 are plated on the inner plate surface and the outer plate surface of the second ceramic board 211, respectively, but not limited thereto. For example, in some embodiments, the second inner metal layer 212 and the second outer metal layer 213 may be formed by direct bonded copper (DBC) technology or formed by using active metal brazing (AMB) technology on the inner plate surface and the outer plate surface of the second carrier 21, respectively.

The second inner metal layer 212 has a second connection pad 2121 and a second carrying region 2122 spaced apart from the second connection pad 2121, and the second inner metal layer 212 comprises a gap formed around the second connection pad 2121. From another perspective, except for the second connection pad 2121, the layout of other parts of the second inner metal layer 212 can be adjusted and changed according to actual needs. For example, the second carrying region 2122 can include multiple parts set at intervals between each other.

More specifically, the material of the second inner metal layer 212 and the material of the second supporting portion 12 are both conductive materials (e.g., copper). The second carrying region 2122 and the second supporting portion 22 may be an integrated single-piece structure formed by a semiconductor process, but not limited thereto. For example, in some embodiments not shown in the instant disclosure, the material of the second inner metal layer 212 and the material of the second supporting portion 22 may be different conductive materials.

The second conductive paste 23 is disposed on the second connection pad 2121 of the first inner metal layer 112, and the second conductive paste 23 may be a sintering silver paste in this embodiment, but not limited thereto.

The power chip 3 has a second surface 332 disposed on the second supporting portion 22. The second bonding pad 32 is connected to the second conductive paste 23 so that the power chip 3 is electrically coupled to the second carrier 21. The annular side edge of the first carrier 11 is preferably flush with the annular side edge of the second carrier 21.

The multiple pins 4 are clamped and fixed between the plurality of supporting parts 121 of the first supporting portion 12 and the second carrier 21. The top edge of each of the pins 4 does not protrude from the second surface 332 of the power chip 3. Each of the pins 4 can be connected and fixed to either the corresponding supporting part 121 or the second carrier 21 through conductive material M (e.g., conductive paste or solder), so that each of the pins 4 is electrically coupled to at least one of the first carrier 11 and the second carrier 21, but not limited thereto.

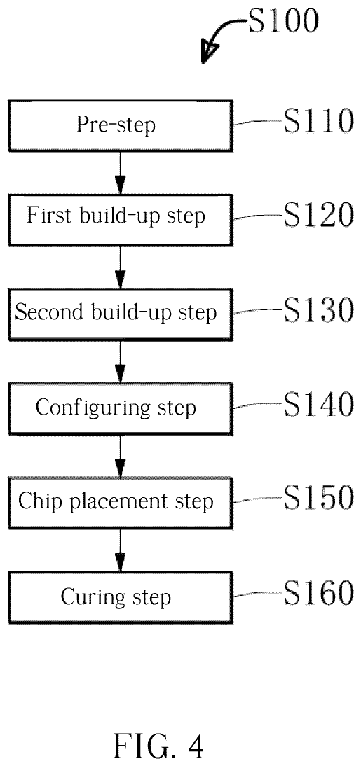

For example, as shown in FIG. 4, the plurality of protrusions 141 of the positioning portion 14 may be located on the inner side of the plurality of pins 4, and the plurality of pins 4 are clamped and fixed between the first supporting portion 12 and the second carrier 21 (not shown in FIG. 4), but not touching the positioning portion 14.

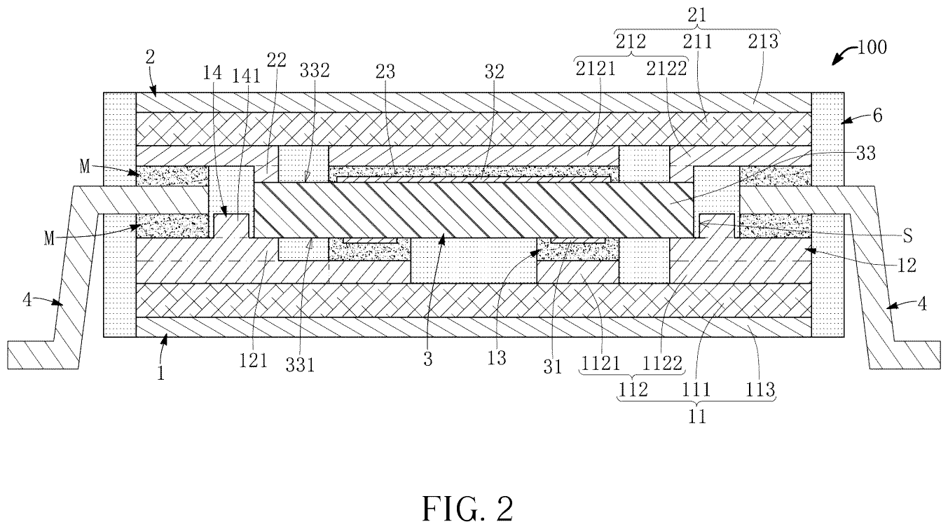

In addition, as shown in FIG. 1 and FIG. 2, the power chip package structure 100 in this embodiment further includes a molding compound 6 so that the first module 1, the second module 2 and the power chip 3 are embedded in the molding compound 6, and part of each pin 4 protrudes from the molded compound 6. The first outer metal layer 113 and the second outer metal layer 213 are exposed from the molding compound 6 to improve the heat dissipation performance.

It should be noted that the number of the second connection pads 2121 and the number of the second conductive paste 23 are each described as one in this embodiment, and correspond to the second bonding pad 32 of the power chip 3, but the present invention is not limited thereto. That is to say, the number of the second connection pads 2121, the number of the second bonding pads 32, and the number of the second conductive paste 23 can also be adjusted to more than one for each according to actual needs.

As disclosed above, the power chip package structure 100 in this embodiment employs the second supporting portions 22 that is interposed between the second carrier 21 and the power chip 3 so that during the production process of the power chip package structure 100, the power chip 3 can be continuously supported by the second supporting portions 22 and maintained in a preset position, thereby preventing the power chip 3 from being tilted relative to the second carrier 21 so as to achieve better reliability.

The above is a structural description of the power chip package structure 100 in this embodiment. Subsequently, as shown in FIG. 2 and FIGS. 4-9, the manufacturing method S100 of the power chip package structure will be briefly introduced. The technical content may be referred to the above description of the power chip package structure 100. However, it is understood that the power chip package structure 100 may be manufactured by other methods, and not limited to the manufacturing method S100.

Further, in order to facilitate understanding of this embodiment, only the manufacturing process between the first module 1 and the power chip 3 will be described below. The manufacturing method S100 of the power chip package structure in this embodiment sequentially includes (or implements) a pre-step S110, a first build-up step S120, a second build-up step S130, and a configuring step S140, a chip placement step S150, and a curing step S160, but not limited thereto. For example, in some embodiments not shown in the instant disclosure, the second build-up step S130 may be omitted according to actual needs.

The pre-step S110: As shown in FIG. 4 to FIG. 6, a first carrier 11 is provided. The first carrier 11 includes a first ceramic board 111 and a first inner metal layer 112 formed on the inner plate surface of the first ceramic board 111. The first inner metal layer 112 includes at least one first connection pad 1121 and a plurality of first carrying regions 1122 spaced apart from each other and located outside of the at least one first connection pad 1121, and the at least one first connection pad 1121 is connected to at least one of the first carrying regions 1122.

The first build-up step S120: As shown in FIG. 4 to FIG. 6, a plurality of supporting portions 121 are respectively formed on the plurality of first carrying regions 1122, which are collectively defined as a first supporting portion 12. The first connection pad 1121 can be electrically coupled to the corresponding supporting part 121 through the first carrying region 1122 to which it is connected.

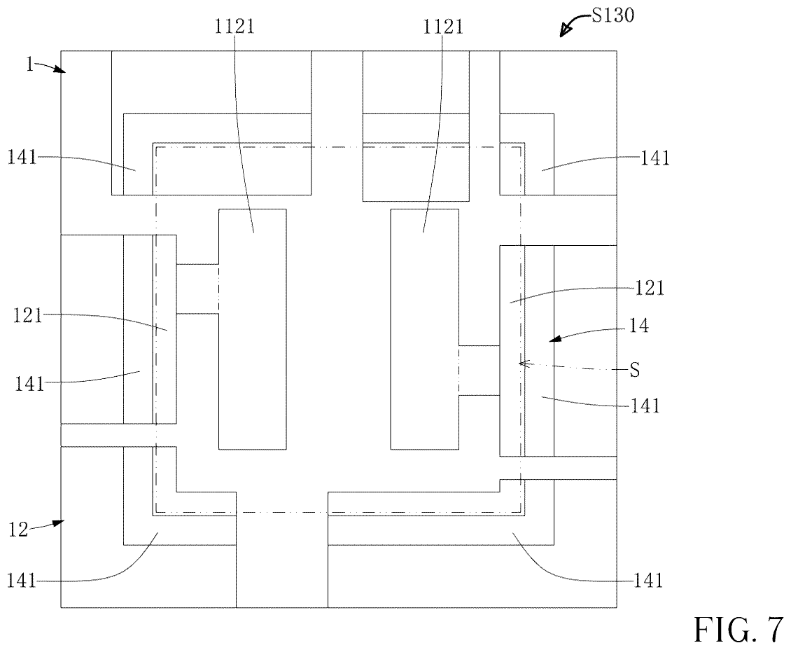

The second build-up step S130: As shown in FIG. 4 and FIG. 7, a positioning portion 14 is formed on the plurality of supporting parts 121 to jointly surround and define a positioning slot S.

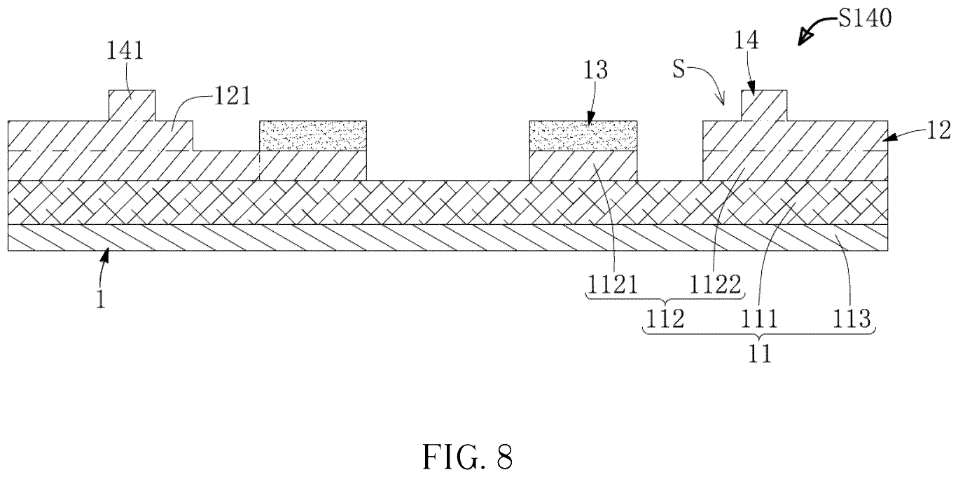

The configuring step S140: As shown in IG. 4 and FIG. 8, at least one first conductive paste 13 is disposed on at least one of the first connection pads 1121, and a top edge of the at least one first conductive paste 13 is not lower than a top edge of the first supporting portion 12. The at least one first conductive paste 13 is preferably further limited to a silver paste, and the at least one first conductive paste 13 can be heated to 130 degrees Celsius in the configuring step S140 to implement pre-drying, but not limited thereto.

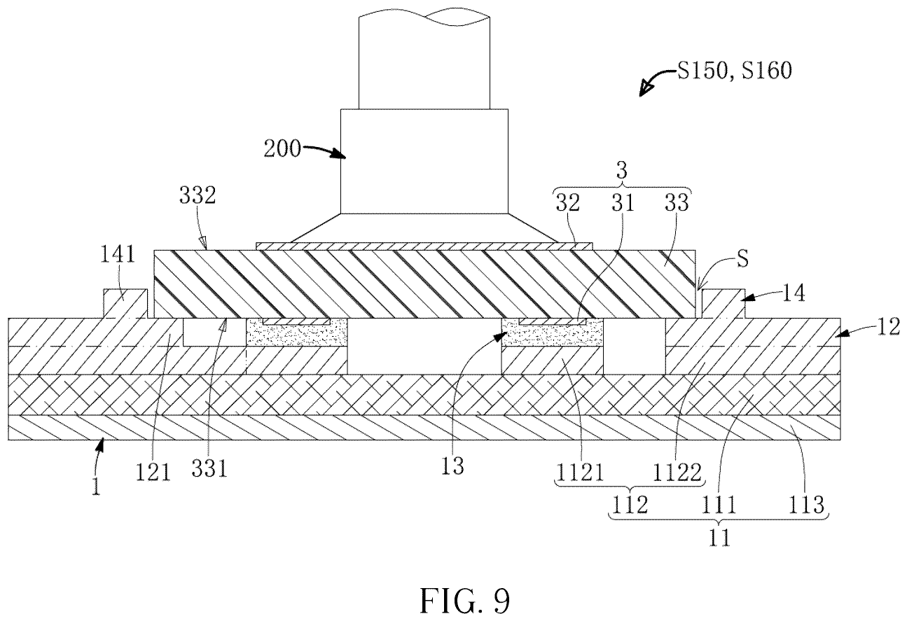

The chip placement step S150: As shown in FIG. 4 and FIG. 9, a power chip 3 is placed on the first supporting portion 12 and the at least one first conductive paste 13 with a jig 200, so that the at least one first bonding pad 31 of the power chip 3 is connected to the at least one first conductive paste 13. The bottom of the power chip 3 is located within the positioning slot S, and the top of the power chip 3 protrudes from the positioning slot S.

The curing step S160: As shown in FIG. 4 and FIG. 9, the at least one first conductive paste 13 is heated and sintered through the jig 200 so that the power chip 3 is fixed on the at least one first conductive paste 13. Furthermore, in this embodiment, the sintering process of the first conductive paste 13 can be pressure-less sintering or pressure-assisted sintering with a specific pressure value according to actual needs. However, the invention is not limited to this.

In addition, the number of the at least one first connection pad 1121, the number of the at least one first conductive paste 13, and the number of the at least one first bonding pad 31 are two for each in this embodiment, but the present invention is not limited to this. Furthermore, the packaging process between the second module 2 and the power chip 3 is similar to the above-mentioned steps S110 to S160. After the second module 2 is installed on the power chip 3, it is further processed to form the molding compound 6 (e.g., FIG. 2) through a packaging step (not shown), and the details will not be described here.

### Embodiment II

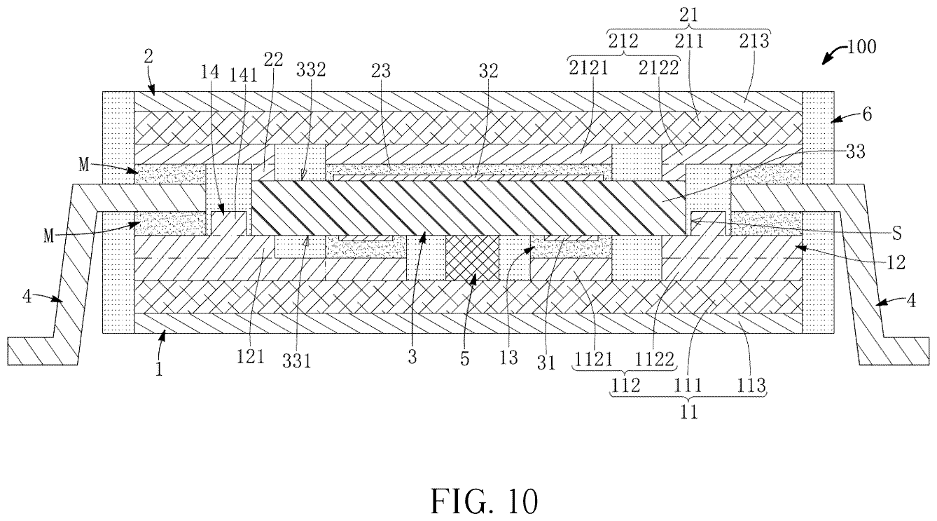

Please refer to FIG. 10, which is Embodiment II of the present invention. Since this embodiment is similar to the above-mentioned Embodiment I, the common features between the two embodiments will not be described in detail. The differences between this embodiment and the above-mentioned Embodiment I are briefly summarized as follows.

In this embodiment, the power chip package structure 100 further includes an insulating supporting member 5 located between the two first connection pads 1121 and clamped between the first ceramic board 111 and the first surfaces 331 of the chip body 33, such that the power chip 3 can be effectively supported. The insulating supporting member 5 can be used as a retaining wall. The insulating supporting member 5 may be a photoresist layer formed by a photolithography process, but not limited thereto.

### Technical Effects of Embodiments of the Present Invention

To sum up, in the power chip package structure and the manufacturing method thereof disclosed in the embodiments of the present invention, the first supporting portion is disposed between the first carrier and the power chip, so that during the production process of the power chip package structure, the power chip can be maintained in a preset position by the first supporting portion, thereby preventing the power chip from being tilted relative to the first carrier, so as to achieve better reliability performance.

Furthermore, the power chip package structure and the manufacturing method disclosed in the embodiment of the present invention further form the positioning portion on the first supporting portion, so that the power chip can be accurately placed on within the positioning slot formed by the positioning portion and the first supporting portion.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a power chip package structure, comprising:
a pre-step: provide a first carrier including a first ceramic board and a first inner metal layer formed on an inner plate surface of the first ceramic board, wherein the first inner metal layer comprises at least one first connection pad, and a plurality of first carrying regions spaced apart from each other and located outside of the at least one first connection pad;
a first build-up step: respectively forming a plurality of supporting parts on the plurality of first carrying regions, which are jointly defined as a first supporting portion;
a configuring step: disposing at least one first conductive paste on the at least one first connection pad, wherein a top edge of the at least one first conductive paste is not lower than a top edge of the first supporting portion;
a chip placement step: using a jig to place a power chip on the first supporting portion and the at least one first conductive paste, so that at least one first bonding pad of the power chip is connected to the at least one first conductive paste; and
a curing step: heating and sintering the at least one first conductive paste through the jig, so that the power chip is fixed on the at least one first conductive paste.

2. The method according to claim 1, wherein number of the at least one first connection pad, number of the at least one first conductive paste, and number of the at least one first bonding pad are two for each, and each of the first connection pads is electrically coupled to one of the plurality of supporting parts.

3. The method according to claim 2, wherein between the first build-up step and the configuring step, the method further includes a second build-up step: forming a positioning portion on the plurality of the supporting parts to jointly define a positioning slot; in the chip placement step, a bottom of the power chip is located within the positioning slot, and a top of the power chip protrudes from the positioning slot.

4. The method according to claim 3, wherein a material of the first inner metal layer and a material of the first support layer are conductive materials, and a material of the positioning portion is insulating material, and the at least one first conductive paste is a silver paste.

5. The method according to claim 1, wherein the power chip further comprises:
a chip body has a first surface and an opposing second surface, wherein two said first bonding pads are formed on the first surface and spaced apart from each other, and are each a source pad and a gate pad, and wherein the chip body is disposed on the first supporting portion with the first surface; and
a second bonding pad formed on the second surface, wherein the second bonding pad is a drain pad.

6. The method according to claim 1, wherein the first carrier is a direct plated copper (DPC) ceramic substrate and includes a first outer metal layer, and the first inner metal layer and the first outer metal layer are respectively plated on the inner plate surface and an outer plate surface of the first ceramic board.

7. A power chip package structure, comprising:
a first carrier, including a first ceramic board and a first inner metal layer formed on an inner surface of the first ceramic board, wherein the first inner metal layer comprises at least one first connection pad, and a plurality of first carrying regions spaced apart from each other and located outside of the at least one first connection pad;
a first supporting portion, including a plurality of supporting parts, which are respectively formed on the plurality of first carrying regions of the first inner metal layer;
at least one first conductive paste disposed on the at least one first connection pad; and
a power chip, comprising:
a chip body having a first surface and an opposing second surface, and the first surface of the chip body is disposed on the first supporting portion; and
at least one first bonding pad formed on the first surface of the chip body, wherein the at least one first bonding pad is connected to the at least one first conductive paste, so that the power chip is electrically coupled to the first carrier.

8. The power chip package structure according to claim 7, wherein the at least one first connection pad is connected to at least one of the plurality of first carrying blocks to be electrically coupled to corresponding one of the plurality of supporting parts.

9. The power chip package structure according to claim 8 further comprising:
a second carrier, including a second ceramic board and a second inner metal layer formed on an inner plate surface of the second ceramic board, wherein the second inner metal layer comprises at least one second connection pad, and a second carrying region spaced apart from the at least one second connection pad;
a second supporting portion formed on the second carrying region of the second inner metal layer; and
at least one second conductive paste disposed on the at least one second connection pad;
wherein the power chip includes at least one second bonding pad formed on the second surface of the chip body, wherein the second supporting portion is disposed on the second surface of the chip body, and the at least one second bonding pad is connected to the at least one second conductive paste, so that the power chip is electrically coupled to the second carrier.

10. The power chip package structure according to claim 9 further comprising a plurality of pins, which are spaced apart from each other and are arranged outside of the power chip, wherein each of the plurality of pins is electrically coupled to at least one of the first carrier and the second carrier.

11. The power chip package structure according to claim 10, wherein a top edge of each of the plurality of pin does not protrude from the second surface of the power chip.

12. The power chip package structure according to claim 9, wherein the first carrier and the second carrier are each a direct plated copper (DPC) ceramic substrate, and the first carrier includes a first outer metal layer, the second carrier includes a second outer metal layer, wherein the first inner metal layer and the first outer metal layer are respectively plated on the inner plate surface and an outer plate surface of the first ceramic board, and the second inner metal layer and the second outer metal layer are respectively plated on the inner plate surface and an outer plate surface of the second ceramic board.

13. The power chip package structure according to claim 9, wherein an annular side edge of the first carrier is flush with an annular side edge of the second carrier.

14. The power chip package structure according to claim 8, wherein number of the at least one first connection pad, number of the at least one first conductive paste, and number of the at least one first bonding pad are two for each, each of the first connection pads is electrically coupled to one of the supporting parts, and the two first bonding pads are respectively a source pad and a gate pad, wherein the power chip further includes a second bonding pad formed on the second surface and the second bonding pad is a drain pad.

15. The power chip package structure according to claim 14, wherein the power chip package structure comprises a positioning portion formed on the plurality of the supporting parts, so that the positioning portion and the supporting parts jointly define a positioning slot, wherein a bottom of the power chip is located within the positioning slot, and a top of the power chip protrudes from the positioning slot.

16. The power chip package structure according to claim 15, wherein a material of the first inner metal layer and a material of the first supporting portion are conductive materials, and a material of the positioning portion is an insulating material, wherein the at least one first conductive paste is a silver paste.

17. The power chip package structure according to claim 8, wherein the power chip package structure adopts a wire-less architecture.
